(19) United States
(12) Patent Application Publication
(10) Pub. No.: US 2008/0182409 A1
(43) Pub. Date: Jul. 31, 2008

(54) METHOD OF FORMING A METAL LAYER OVER A PATTERNED DIELECTRIC BY ELECTROLESS DEPOSITION USING A SELECTIVELY PROVIDED ACTIVATION LAYER

(76) Inventors: Robert Seidel, Dresden (DE); Axel Preusse, Radebeul (DE); Ralf Richter, Dresden (DE)

Correspondence Address: J. Mike Amerson;Williams, Morgan & Amerson, P.C., Suite 1100, 10333 Richmond, Houston, TX, 77042, US

(21) Appl. No.: 11/782,987

(22) Filed: Jul. 25, 2007

(30) Foreign Application Priority Data
Jan. 31, 2007 (DE) 10 2007 004 884.1

(51) Int. Cl. H01L 21/445

(52) U.S. Cl. 438/678; 257/E21.479

(57) ABSTRACT

By forming an activation/nucleation layer selectively at a bottom of an opening, efficient electroless deposition techniques may be used for forming contacts, vias and trenches of advanced semiconductor devices. By selectively providing the activation material, a self-aligned bottom-to-top fill behavior may be obtained.

### BACKGROUND OF THE INVENTION

1. Field of the Invention

The present disclosure generally relates to the field of integrated circuits, and, more particularly, to the formation of metal layers over a patterned dielectric material, such as trenches and vias, contact plugs and the like, by a wet chemical deposition process, such as electroless plating.

2. Description of the Related Art

In an integrated circuit, a large number of circuit elements, such as transistors, capacitors, resistors and the like, are formed in or on an appropriate substrate, usually in a substantially planar configuration. Due to the large number of circuit elements and the required complex layout of advanced integrated circuits, generally the electrical connection of the individual circuit elements may not be established within the same level on which the circuit elements are manufactured, but requires one or more additional “wiring” layers, also referred to as metallization layers. These metallization layers generally include metal lines, providing the inner-level electrical connection, and also include a plurality of inter-level connections, also referred to as vias, when connections to other metal lines are considered, whereas respective vertical connections to contact areas of circuit elements, such as transistors, may be referred to as contacts or contact plugs. For convenience, respective electrical connections including metal lines and/or vias and/or contacts may hereinafter be commonly referred to as interconnects or interconnect structures.

Due to the continuous shrinkage of the feature sizes of circuit elements in modern integrated circuits, the number of circuit elements for a given chip area, that is the packing density, also increases, thereby requiring an even larger increase in the number of electrical interconnections to provide the desired circuit functionality. Therefore, the number of stacked metallization layers may increase as the number of circuit elements per chip area becomes larger. Similarly, the available floor space for contacts is also reduced. Since the fabrication of a plurality of metallization layers entails extremely challenging issues to be solved, such as mechanical, thermal and electrical reliability of several stacked metallization layers that are required, for example, for sophisticated microprocessors, semiconductor manufacturers are increasingly replacing the well-established materials, such as aluminum, with a metal that allows higher current densities and hence allows a reduction in the dimensions of the interconnections. For example, copper is a metal generally considered to be a viable candidate for being used in a plurality of interconnect structures due to its superior characteristics in view of higher resistance against electromigration and significantly lower electrical resistivity when compared with, for instance, aluminum. In spite of these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD) and physical vapor deposition (PVD), and also may not be effectively patterned by the usually employed anisotropic etch procedures due to copper's characteristics to form non-volatile reaction products. In manufacturing metallization layers including copper, the so-called damascene technique is therefore preferably used, wherein a dielectric layer is first applied and then patterned to define trenches and vias, which are subsequently filled with copper. Similar process strategies are also applied in the contact level, where a dielectric layer is formed to passivate the semiconductor devices while in a later stage respective contact openings are formed and filled with an appropriate conductive material, such as a metal, an alloy and the like.

Due to the high diffusivity of a plurality of conductive materials, such as copper, it is frequently necessary to employ a so-called barrier material in combination with the actual metallization material to substantially avoid any out-diffusion of the metal into the surrounding dielectric material, as, for instance, copper may then readily migrate to sensitive semiconductor areas, thereby significantly changing the characteristics thereof. Since the dimensions of the trenches and vias currently approach a width or a diameter of approximately 0.1 μm and even less with an aspect ratio of the vias of about 5 or more, advanced deposition techniques have been developed to reliably form a barrier layer on exposed surfaces of the openings.

However, for completely filling respective openings, such as contact openings, vias, trenches and the like, in a reliable and substantially void-free manner, complex deposition techniques may be required, wherein, for instance, in well-established techniques for forming copper-based metallization layers, an electroplating process may be used for obtaining a substantially bottom-to-top fill behavior, where the copper material is substantially deposited from bottom to top followed by a removal of any excess material on the basis of chemical mechanical polishing (CMP) and/or electrochemical etch processes. Since the corresponding electrochemical process is driven by an external current flowing through the electrolyte solution, a respective current distribution layer is required, thereby initiating a deposition of the metal on surface areas covered by the respective current distribution layer. Thus, although the electroplating process may provide an efficient fill process due to the significantly increased deposition rate compared to other techniques, in particular if advanced metal compositions are considered, such as copper and the like, which might not be efficiently deposited in larger amounts by CVD, PVD and the like, significant efforts may be required for providing a desired degree of selectivity during the deposition process. Furthermore, the electroplating process may require highly complex chemistries, since, in high aspect openings, the deposition process may also proceed at sidewall portions of the respective opening due to the presence of the corresponding currents distribution layer at all exposed surfaces, which may result in a pinch-off at the upper portion of the opening prior to completely filling the remaining volume of the opening, unless complex current pulse patterns in combination with sensitive additives are used for significantly increasing the vertical growth rate compared to the horizontal growth rate. Furthermore, the different growth directions, although occurring in very different growth rates, and the complex chemistries, used in the above-mentioned complex compensation mechanisms, may result in non-desired crystallinity, i.e., grain structure, of the resulting metal structure, thereby also requiring complex post-deposition treatments in order to provide the desired crystallinity and texture of the resulting metal structure. Consequently, with every new device generation, requiring even further reduced cross-sections of the respective interconnect structures, even further restrictive requirements may have to be fulfilled, since increased current densities may require enhanced electromigration behavior of the corresponding interconnect structures. Therefore, enhanced crystallinity in combination with a void-free filling of the high aspect ratio opening may thus represent critical aspects for the further device scaling.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein addresses the problems encountered in conventional process regimes with respect to forming metal-containing regions in advanced semiconductor devices in that efficient electroless deposition processes may be used for filling the corresponding openings with a high degree of selectivity, without requiring respective current distribution layers as is the case in electroplating processes. Since typically an electrochemical process without external current flow may require an activation energy or a corresponding catalyst or nucleation material, a respective material may be selectively provided on the surface areas of openings, at which a corresponding deposition of the metal-containing material is desired. That is, the bottom of a respective opening may receive, or may have an exposed surface of, a corresponding activation material or a catalyst material in a highly selective manner, thereby providing the possibility of substantially determining the growth direction in the subsequent electrochemical deposition process and accomplishing a highly reliable bottom-to-top fill behavior. Furthermore, since the corresponding catalyst material may be provided in a highly selective manner, any pinch-off effects at upper portions of the opening may be significantly reduced, thereby resulting in enhanced fill capability, which may allow further device scaling required in future device generations. Furthermore, the provision of substantially a single growth direction during the electrochemical deposition process may provide the possibility of efficiently controlling the resulting crystallinity of the metal-containing material without complex post-deposition treatments.

According to one illustrative embodiment, a method comprises providing an exposed surface of an activation layer selectively at a bottom of an opening that is formed in a material layer of a semiconductor device, wherein the activation layer comprises a species for initiating an electrochemical deposition process when being in contact with a specified electrolyte solution. The method further comprises applying the specified electrolyte solution in the opening to perform an electrochemical process for filling the opening with a conductive material from bottom to top on the basis of the exposed surface of the activation layer.

According to another illustrative embodiment, a method comprises forming an opening in a material layer of a semiconductor device and providing an exposed catalyst material selectively at a bottom of the opening, wherein the catalyst material is configured to initiate an electrochemical reaction upon contact with a specified electrolyte solution. Finally, the method comprises filling the opening from bottom to top with a metal-containing material by applying the specified electrolyte solution.

According to yet another illustrative embodiment, a method comprises forming an activation layer on a restricted area of a semiconductor device and forming a dielectric layer above the restricted area. Furthermore, an opening is formed in the dielectric layer so as to expose a portion of the activation layer and the opening as filled by an electrochemical deposition process using the exposed portion of the activation layer for initiating the electrochemical deposition process.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of a semiconductor device including a material layer having formed therein respective openings, such as a contact opening (FIG. 1a), a via opening (FIG. 1b) and a trench for a metal line (FIG. 1c), in which the efficient electrochemical deposition technique of illustrative embodiments may be used;

FIGS. 1d-1f schematically illustrate cross-sectional views of a material layer having formed therein an opening to be filled with a metal-containing material on the basis of an electroless deposition process according to further illustrative embodiments;

FIGS. 1h-1i schematically illustrate cross-sectional views of an opening during various manufacturing stages, wherein unwanted portions of an activation layer are removed prior to initiating the electrochemical deposition process according to yet other illustrative embodiments;

FIGS. 2a-2c schematically illustrate cross-sectional views of a semiconductor device during various manufacturing stages in forming an opening on the basis of a selectively provided activation layer according to yet other illustrative embodiments;

FIG. 2d schematically illustrates a cross-sectional view of the semiconductor device as shown above, wherein material of the activation layer may be efficiently removed from horizontal portions of the device outside the opening and from sidewall portions according to yet other illustrative embodiments; and

FIGS. 3a-3d schematically illustrate cross-sectional views of a semiconductor device during various manufacturing stages, wherein an activation layer may be selectively formed prior to forming the corresponding opening according to other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to highly efficient electrochemical deposition processes on the basis of a catalyst material or an activation layer, which may be selectively provided or at least exposed at specific surfaces of an opening, for instance, after forming the opening or prior to forming the opening, in order to define a substantially single deposition growth direction within the opening during a corresponding electroless fill process. In this way, superior fill characteristics in terms of deposition rates, crystallinity, contaminations and the like may be accomplished compared to other process techniques, such as chemical and physical vapor deposition, especially if highly complex metal alloys and/or critical metal components, such as copper, silver and the like, have to be used. The electroless deposition process typically requires an active initiation of the chemical reaction of the agents contained in the corresponding plating solution in order to reduce and thus deposit the corresponding components to form a uniform layer. Typically, the initiation of the chemical reaction may be accomplished by a catalytic material or on the basis of respective nucleation centers of small size in order to not unduly compromise the crystallinity of the material deposited. For example, material such as platinum (Pt), palladium (Pd), copper (Cu), silver (Ag), cobalt (Co) and the like are known as highly efficient catalyst materials for activating the chemical reaction between a metal salt and a reducing agent contained in a corresponding electrolyte solution. Consequently, by selectively providing a corresponding activation layer at an exposed surface portion of an opening, a corresponding deposition process may be initiated, wherein it may not even be necessary to form a substantially continuous activation layer as long as sufficient nucleation or activation centers may be present. Consequently, a wide class of metal materials including respective alloys may be efficiently filled in high aspect ratio openings, such as contact openings, via openings, trenches for metal lines and the like, in order to provide superior fill capabilities in combination with enhanced deposition rates and possibly in combination with superior crystallinity of the corresponding metal region. In this way, the overall performance of respective interconnect structures may be enhanced, since the overall behavior with respect to stress-induced mass transport phenomena within interconnect structures may significantly depend on the crystalline quality, the absence of any voids and, thus, internal surfaces in the metal material and the quality of respective interfaces to other materials, such as dielectrics, metal alloys and the like.

With reference to the accompanying drawings, further illustrative embodiments for efficiently forming interconnect structures on the basis of an electroless deposition process will now be described in more detail.

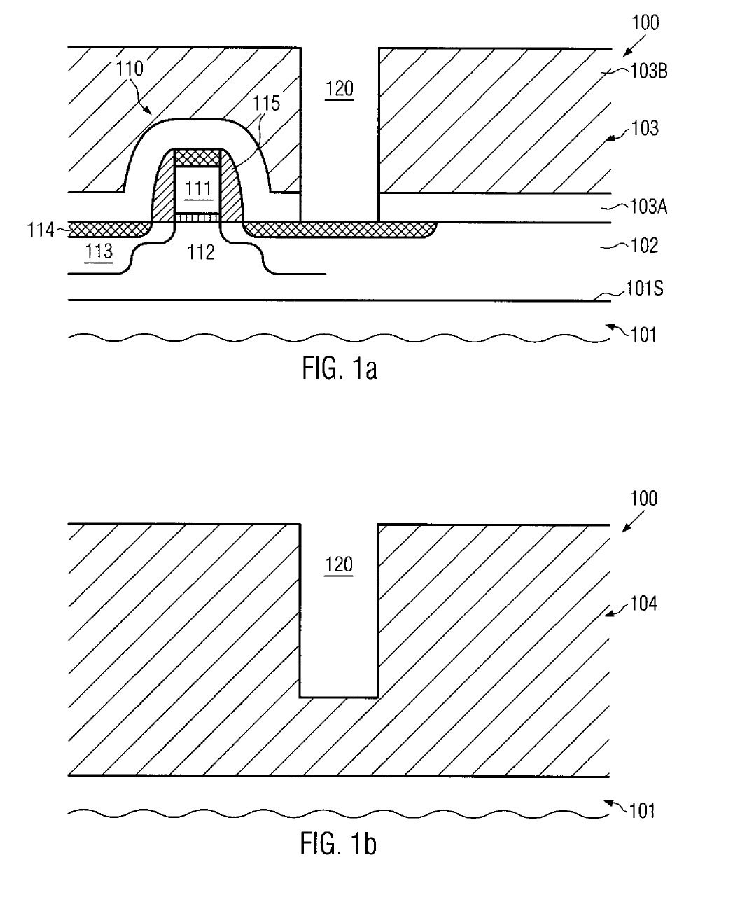

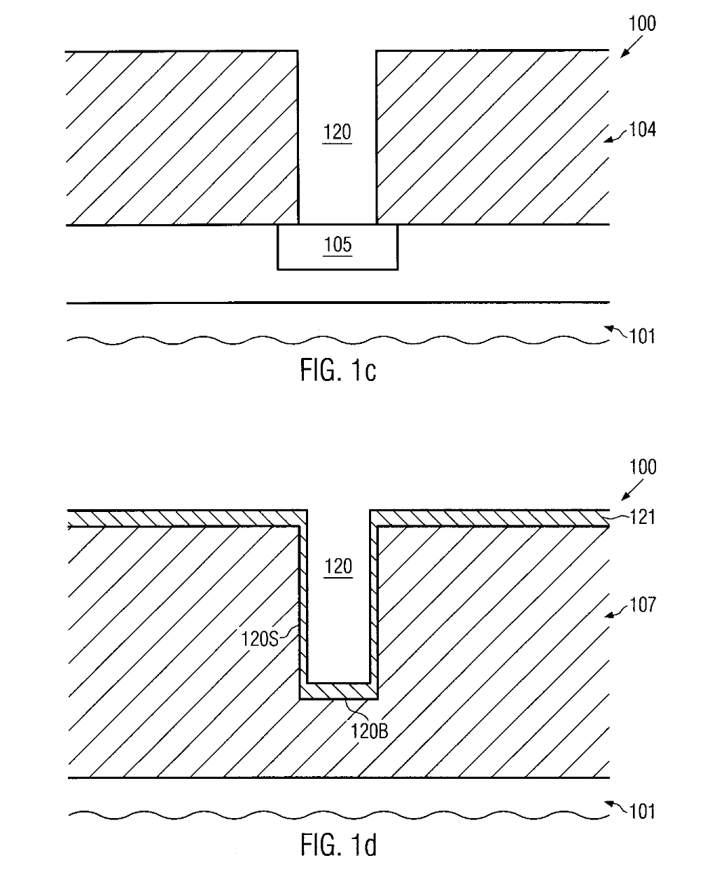

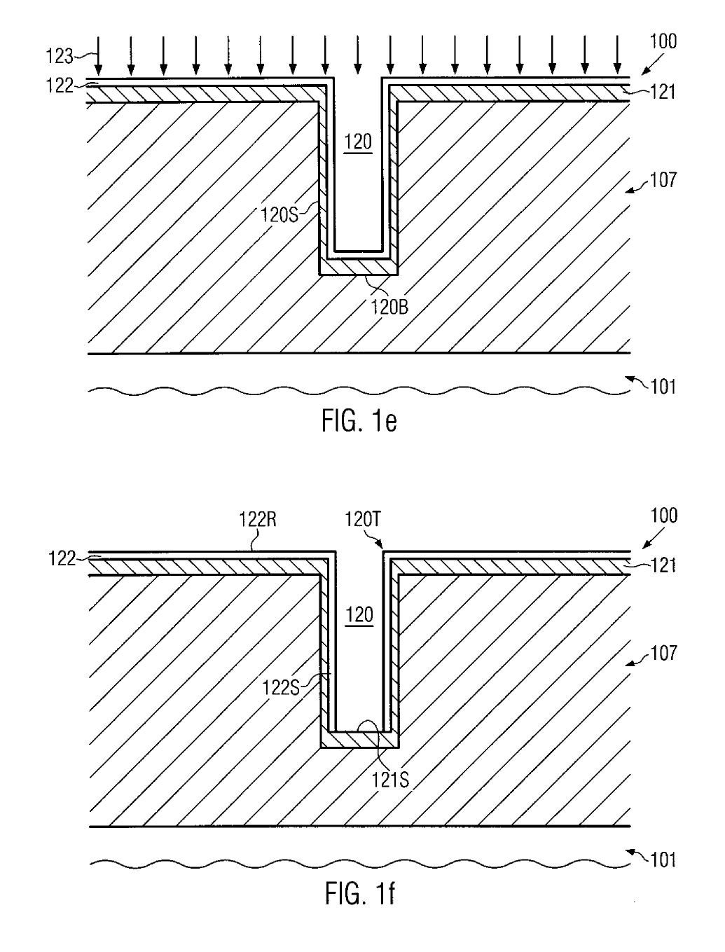

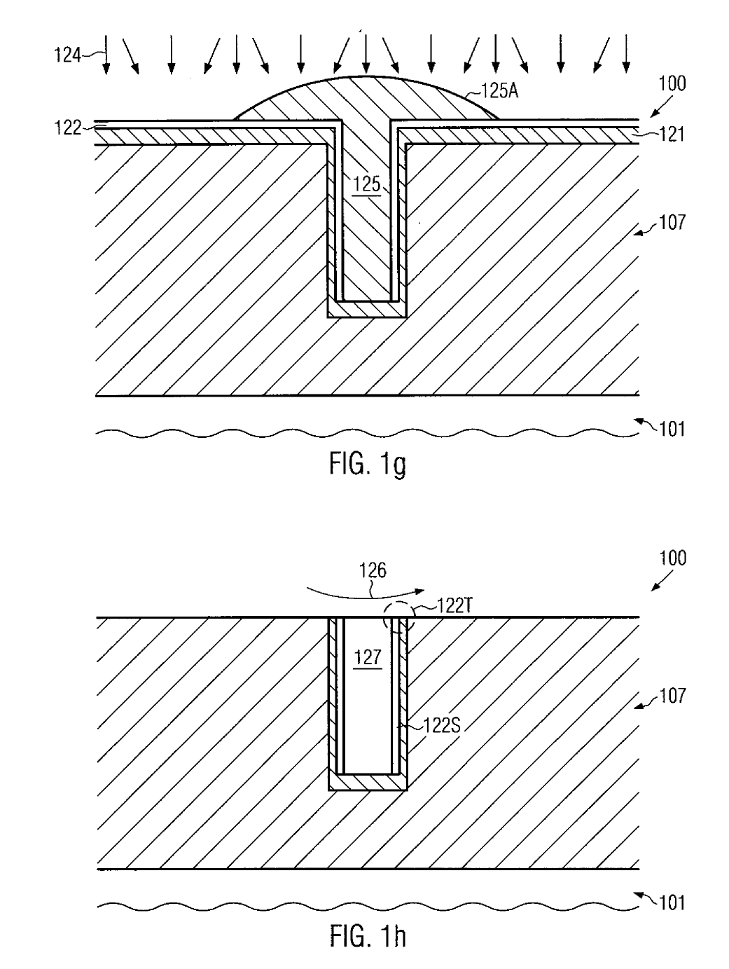

FIG. 1a schematically illustrates a cross-sectional view of a semiconductor device 100 comprising a substrate 101, in and on which respective circuit elements may be formed. For convenience, the semiconductor device 100 as shown in FIG. 1a may represent a situation in which a circuit element, such as a transistor 110, may receive a corresponding contact or contact plug connected to a corresponding contact area of the circuit element 110. In this case, the semiconductor device 100 may comprise a respective semiconductor layer 102, which may represent any appropriate semiconductor material for forming therein and thereon the transistor element 110. For instance, the semiconductor layer 102 may represent a silicon-based material, which may, in some illustrative embodiments, also include other components, such as germanium and the like. In other cases, the semiconductor layer 102, in combination with the substrate 101, may represent a silicon-on-insulator (SOI) configuration, wherein the semiconductor layer 102 may be vertically separated from the substrate 101 by a buried insulating layer (not shown).

In this respect, it should be appreciated that any positional statements, such as “above,” “below,” “horizontal,” “vertical,” bottom,” “top” and the like, are to be understood as relative positional information, wherein the substrate 101 or a specified surface thereof, such as a surface 101S may be considered as a reference. That is, a dielectric layer stack 103 may be considered as being provided above the semiconductor layer 102, since the distance of the dielectric layer stack 103 with respect to the substrate 101 or the surface 101S is greater than the corresponding distance of the semiconductor layer 102. Similarly, a gate electrode 111 of the transistor 110 is formed “on” a gate insulation layer 112, which in turn is formed “on” the semiconductor layer 102. Similarly, a vertical direction is substantially perpendicular to the substrate 101 or the surface 101S, while a horizontal direction is substantially parallel to the surface 101S.

It should further be appreciated that the transistor 110 may have any appropriate configuration, depending on the respective device architecture. In the illustrative embodiment shown, the transistor 110 may further comprise a sidewall spacer structure 115 and corresponding drain and source regions 113, which may have incorporated therein respective metal silicide regions 114, when a corresponding reduction of the contact resistance may be desired. In this case, the metal silicide regions 114, or at least one of these regions, may act as a contact area of the transistor 110. In other cases, respective contact areas may be provided in the form of highly doped semiconductor material, such as polycrystalline silicon, silicon/germanium and the like. Furthermore, the dielectric layer stack 103 may comprise one or more materials, such as any appropriate dielectrics 103B providing the desired mechanical and electrical performance, and other materials, such as an etch stop material 103A, for instance comprised of silicon nitride, silicon dioxide, stressed silicon nitride and the like. Moreover, the material 103B may provide the desired passivating characteristics and may also act as a first interlayer dielectric material, above which one or more respective metallization layers are to be formed. In this manufacturing stage, a respective opening 120 may be formed in the dielectric layer stack 103 so as to extend to the respective contact area, which in this case may be represented by the metal silicide region 114.

It should be appreciated that lateral dimensions of respective components, such as the horizontal extension of the gate electrode 111, which is also referred to as gate length, may be 50 nm and less, wherein even further reduced dimensions may occur in further device generations. Similarly, a respective lateral dimension of the opening 120 may be within a similar order of magnitude, thereby requiring efficient fill capabilities as is previously explained. The opening 120 may represent one device configuration in which corresponding deposition recipes, as previously referred to and explained hereinafter in more detail, may be advantageously applied.

FIG. 1b schematically illustrates the semiconductor device 100, wherein the opening 120 may be formed within a dielectric layer 104, which may represent the dielectric material of one of the plurality of metallization layers to be formed above the substrate 101. For instance, in a lower level or device layer, the corresponding circuit elements 110 may be formed and thereafter a plurality of metallization layers may have to be provided to establish the corresponding electrical connections in accordance with that circuit layout. Thus, the opening 120 as shown in FIG. 1b may represent a trench, to which the electroless deposition techniques disclosed therein may be efficiently applied.

FIG. 1c schematically illustrates the semiconductor device 100 according to further illustrative embodiments, wherein the opening 120 may be formed in a dielectric layer, such as a layer 114, so as to connect to a lower lying metal region 105 which may represent a metal line of a lower lying metallization layer. Thus, the opening 120 may be considered as a via opening as previously explained.

The semiconductor device 100 as illustrated in FIGS. 1a-1c may represent illustrative examples of situations in which an appropriate metal-containing material has to be filled in the openings 120 and hereinafter it may only be referred to as an opening in the semiconductor device, wherein it should be borne in mind that at least any of the situations described with reference to FIGS. 1a-1c may be contemplated by the subject matter disclosed herein.

It should be appreciated that the semiconductor device 100 as shown in FIGS. 1a-1c may be formed on the basis of well-established techniques in accordance with the specific design rules. That is, respective process sequences for forming the transistor 110 including sophisticated lithography, deposition, etch, implantation, anneal and other processes may be performed. Similarly, respective metallization levels may be formed on the basis of established process techniques, wherein respective high aspect ratio openings may be filled on the basis of process techniques as previously described and as will also be described in more detail later on. Thus, it should be appreciated that the corresponding process techniques may be used in each of the respective metallization layers of complex semiconductor devices, including other microstructure devices, and also in the contact level as is for instance shown in FIG. 1a.

FIG. 1d schematically illustrates the semiconductor device 100, wherein the opening 120 is formed in a material layer, which may now be referred to as layer 107, which may represent any of the dielectric layer 103, 104 or other material layers, when the corresponding opening 120 formed therein has to be filled with an appropriate metal-containing material. In this manufacturing stage, an activation layer 121 may be formed on exposed surface portions of the opening 120, that is on sidewall portions 120S and a bottom surface 120B. Furthermore, the activation layer 121 may also be formed on horizontal portions of the material layer 107. As previously explained, the activation layer 121 may comprise any appropriate catalyst material, for instance as specified above, which may enable the initiation of the chemical reaction during a subsequent electroless deposition process as previously explained. The activation layer 121 may, in some illustrative embodiments, further be comprised of, when critical metal materials are to filled in the opening 120, a material composition providing the desired adhesion and diffusion blocking characteristics and/or providing a moderately low resistivity when the opening 120 may represent a corresponding contact or via for providing electrical contact to a lower lying contact area or metal region. In some illustrative embodiments, the activation layer 121 may be provided as a substantially continuous material composition including an appropriate catalyst material, such as platinum, palladium and the like. In other illustrative embodiments, the activation layer 121 may include a corresponding catalyst material at a surface portion thereof, in order to initiate the corresponding chemical reaction, while other portions of the activation layer 121 may provide other desired characteristics, such as adhesion, low contact resistivity and the like. The activation layer 121 may be formed on the basis of appropriate deposition techniques, such as plasma enhanced chemical vapor deposition (PECVD), PVD and the like. In some illustrative embodiments, the activation layer 121 may be comprised of an efficient barrier material, such as tantalum, titanium and the like, when respective diffusion blocking characteristics may be necessary. In other cases, the activation layer 121 may be formed on the basis of sophisticated techniques, such as atomic layer deposition (ALD) processes, which typically exhibit a self-limiting deposition behavior. Thus, in this case, an extremely reduced layer thickness may be achieved while nevertheless providing reliable coverage of any exposed surface portions within the opening 120. In other illustrative embodiments, the moderately high directionality of physical vapor deposition techniques, such as sputter deposition, may be taken advantage of since, here, the deposition rate at horizontal surface portions may be increased compared to a respective deposition rate at the sidewall portions 120S. In this case, the catalyst material in the activation layer 120 may be efficiently removed from the sidewall portions 120S, as will be described later on in more detail.

In still other illustrative embodiments, the catalyst material in the activation layer 121 may be introduced into a surface area thereof on the basis of an ion implantation process, thereby creating a desired high concentration of the respective catalyst material at the bottom 120B, while significantly restricting the corresponding concentration at the sidewalls 120S. Thus, a high degree of anisotropy with respect to the catalytic characteristics of the activation layer 121 may be created within the opening 120, which may be even further enhanced by, for instance, performing an isotropic etch process, thereby efficiently removing a moderately thin surface portion of the activation layer 121 while maintaining a sufficient amount of catalyst material at the bottom 120B and also efficiently removing the corresponding catalyst material from the sidewall portions 120S. It should be appreciated that a corresponding implant species in horizontal portions of the activation layer 121 outside the opening 120 may be removed on the basis of process strategies as described later on.

FIG. 1 e schematically illustrates the semiconductor device 100 in a further advanced manufacturing stage. A spacer layer 122 may be formed on the activation layer 121, wherein the spacer layer 122 may have appropriate adhesion and/or barrier characteristics that are compatible with the corresponding material to be filled into the opening 120 in a later electroless deposition process. For instance, the spacer layer 122 may be comprised of well-established barrier materials for metallization layers, contact plugs and the like and may be selected in accordance with device requirements. For example, the spacer layer 122 may be provided in the form of a tantalum layer when a copper-based material is to be filled into the opening 120. The spacer layer 122 may be formed on the basis of any well-established deposition techniques, such as CVD, sputter deposition, PECVD and the like. For example, in a corresponding deposition process, the process parameters may be selected so as to result in a reduced deposition rate at the bottom 120B compared to horizontal portions outside the opening 120. A corresponding deposition behavior may typically be encountered in CVD-based processes due to the significantly increased surface area within the opening 120 with respect to any incoming particles compared to the horizontal areas outside the opening 120. Similar process conditions may also be established for sputter deposition processes, when the directionality is reduced.

Thereafter, the device 100 may be exposed to an anisotropic etch ambient 123 in order to remove material of the layer 122 from horizontal portions and, in particular, from the bottom 120B while maintaining the material at the sidewalls 120S. The anisotropic etch process 123 may be designed as a selective etch process with respect to the activation layer 121, while in other cases the selectivity of the process 123 may be less critical, in particular when an increased layer thickness of the activation layer 121 may be provided at the bottom 120B, thereby providing moderately wide process margins. In some illustrative embodiments, the anisotropic etch process 123 may be designed so as to exhibit a moderately high physical component, i.e., a moderately high degree of ion bombardment, thereby generating a sputter-like behavior, wherein material from the bottom 120B may be redistributed to the sidewalls 120S, whereas, in the horizontal portions outside the opening 120, the respective material removal may be reduced due to an immediate re-deposition. Hence, in this case, the activation layer 121 at the bottom 120B may be exposed prior to exposing horizontal portions of the layer 121 outside the opening 120, thereby maintaining a portion of the spacer layer 122 outside the opening 120. In other cases, the corresponding effect may be enhanced by creating a reduced layer thickness of the spacer layer 122 at the bottom, as previously explained.

FIG. 1f schematically illustrates the semiconductor device 100 after the anisotropic etch process 123 according to some illustrative embodiments. In the example shown, a remaining portion 122R of the spacer layer 122 may be provided at horizontal portions outside the opening 120, while the bottom thereof may be exposed, i.e., the activation layer 121 may provide an exposed surface including the catalyst material, as previously explained. Furthermore, due to the high anisotropic nature of the etch process 123, respective sidewall spacers 122S may cover the activation layer 121 at the sidewalls 120S. Consequently, the activation layer 121 at the top of the opening 120, indicated as 120T, may be reliably covered by material of the spacer layer 122, thereby substantially avoiding any catalyzing activity during a subsequent electroless deposition process. Consequently, upon applying a respective electrolyte solution, which may comprise the salt of a desired metal and a respective reducing agent, the exposed surface 121S may provide a respective catalyst material or nucleation centers in order to start the corresponding deposition of metal material. Consequently, the resulting deposition direction is substantially determined by the surface 121S, thereby providing an enhanced bottom-to-top fill behavior, since the sidewall spacers 122S may efficiently suppress a lateral growth of the corresponding metal material. Similarly, the reliable coverage of the top surface 120T may also suppress undue growth of metal material, which may otherwise result in a corresponding pinch-off at the top surface 120T.

FIG. 1g schematically illustrates the semiconductor device 100 during a corresponding electrochemical deposition process 124, thereby reliably filling the opening 120 with a metal-containing material 125. The corresponding electroless deposition process 124 may be performed with a certain amount of over-deposition time so as to reliably fill a plurality of openings 120, which may have different lateral dimensions across the entire substrate 101. Hence, a certain amount of excess material 125A may be formed due to the lateral growth of the material 125, when reaching the top surface 120T. The corresponding excess material 125A may be efficiently removed on the basis of CMP and the like, wherein the horizontal portion 122R of the spacer material and of the activation layer 120 may also be removed.

Consequently, the opening 120 may be reliably filled with the material 125 in a bottom-to-top fashion on the basis of a high deposition rate, wherein any appropriate material, such as copper, silver, cobalt, nickel or alloys thereof, may be provided depending on the device requirements.

FIG. 1h schematically illustrates the semiconductor device 100 in accordance with still further illustrative embodiments. In this manufacturing stage, the respective spacer layer 122 may have been formed, for instance on the basis of any appropriate deposition technique, wherein the subsequent etch process 123 may also expose portions of the layer 121 outside the opening 120 due to process variations, a respective process recipe, which may now provide increased layer thickness of the spacer layer 122 outside the opening 120, and the like. In this case, the activation layer 121 at horizontal portions outside the opening 120 may be removed on the basis of a CMP process 126, wherein, prior to performing the CMP process 126, an appropriate fill material 127 may be deposited in a highly non-conformal manner. For instance, the fill material 127 may be comprised of a polymer material, a resist material and the like, which may be applied on the basis of spin-on techniques or any other highly non-conformal deposition mechanisms in order to fill the opening 120 and, thus, “protect” the opening 120 and the corresponding layers formed therein, i.e., the exposed surface of the activation layer 121 at the bottom 120 and the spacers 122S formed during the preceding anisotropic etch process 123. Thus, by removing any residuals of the layer 121 by the CMP process 126, a corresponding metal deposition at the top 120T of the opening 120 may be significantly reduced. In some aspects, if the corresponding catalyst material may be provided at surface areas of the activation layer 121 only, for instance by performing a respective ion implantation process, as previously described, a significant growth rate at the portion 121T of the activation layer 121 may not be observable, thereby substantially not contributing to a significant influence on the overall growth behavior of the electrochemical deposition process.

FIG. 1i schematically illustrates the semiconductor device 100 during the process 124, wherein the corresponding material growth 125 is substantially restricted in the vertical direction due to the exposed surface 121 S while a significant material deposition outside the opening 120 may be efficiently suppressed. Consequently, by removing material of the layers 121, possibly in combination with residuals of the spacer layer 122, by a corresponding “masked” CMP process on the basis of the fill material 127, enhanced flexibility in designing the corresponding deposition processes for the layers 121 and 122, as well as for the subsequent anisotropic etch process 123, may be achieved since an exposure of the activation layer 121 during the etch process 123 is not critical and may not significantly affect the vertical growth of the material 125. Consequently, the opening 120, irrespective of which of the situations illustrated in FIGS. 1a-1c is addressed, may be efficiently filled with an appropriate metal-containing material on the basis of the electroless deposition process 124.

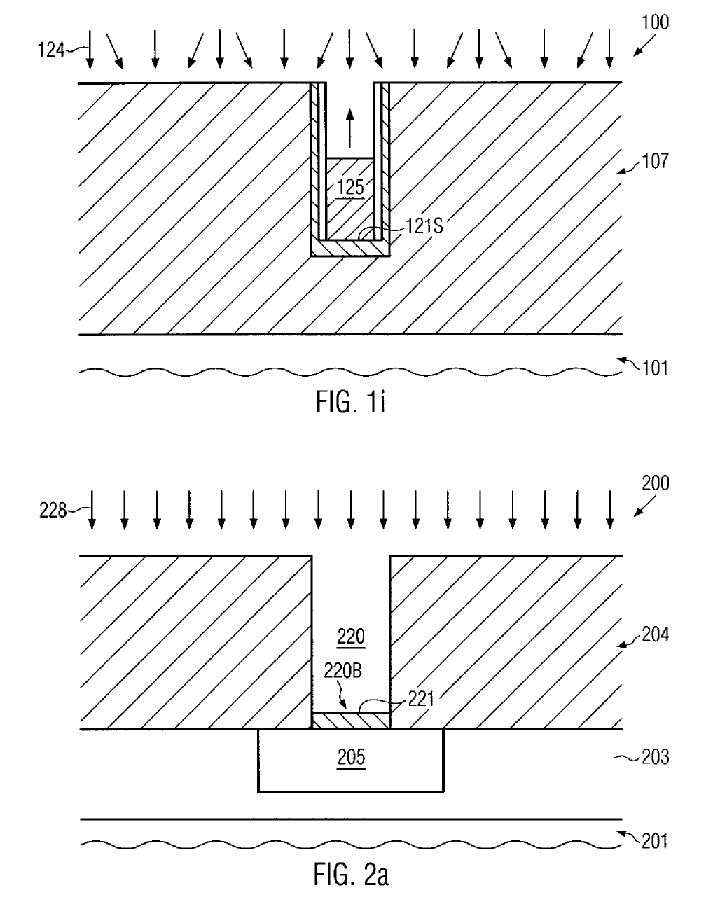

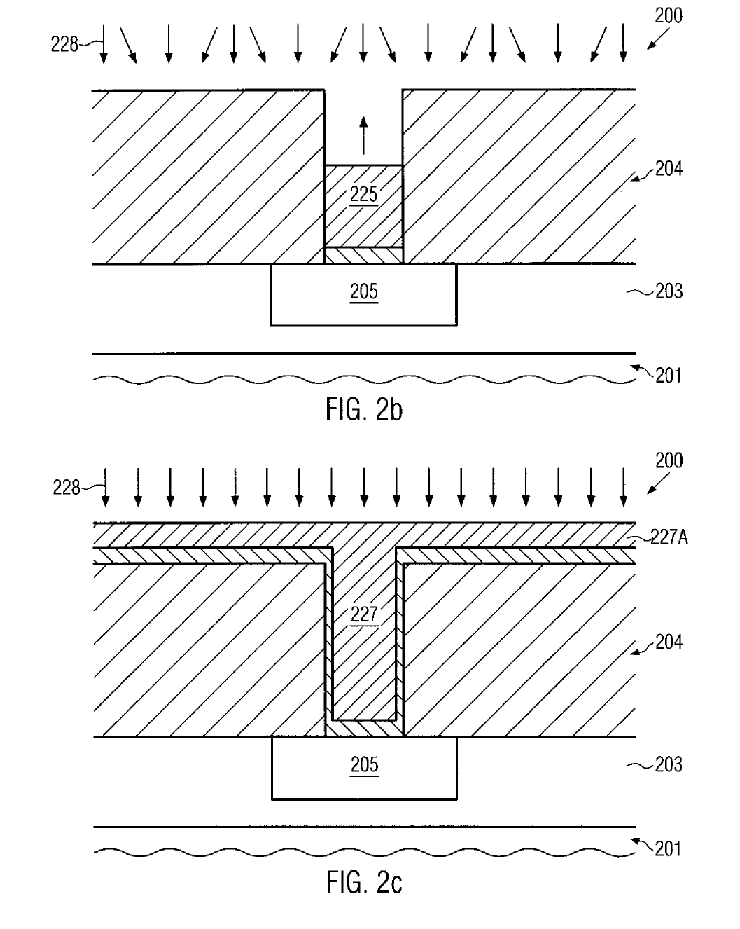

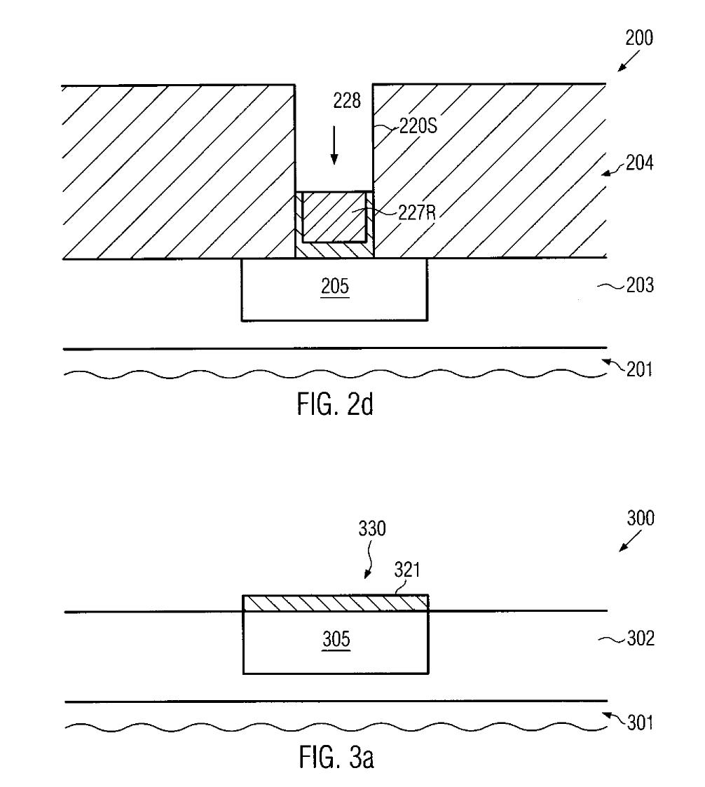

With reference to FIGS. 2a-2e, further illustrative embodiments will now be described, wherein a corresponding catalyst material or activation layer may be selectively provided at the bottom of an opening, such as a via opening or a contact opening, as previously described with reference to FIGS. 1a and 1c.

FIG. 2a schematically illustrates a cross-sectional view of a semiconductor device 200 comprising a substrate 201 having formed thereabove a dielectric layer 203, in which may be provided a conductive region 205, such as a metal region or a contact area, as previously described. Furthermore, a second dielectric layer 204 may be formed above the layer 203 and may have provided therein an opening 220 with a bottom portion 220B formed by an activation layer 221. With respect to the components described so far, it may be referred to corresponding components described with reference to the semiconductor device 100.

The layer 203 including the conductive region 205 and possibly any circuit elements formed in and above the substrate 201 may be manufactured on the basis of well-established techniques, as are also described with reference to the device 100. Thereafter, the dielectric layer 204, which may be comprised of appropriate dielectric materials, such as low-k dielectric materials, silicon dioxide, silicon nitride, or any other appropriate dielectric materials in accordance with device requirements, may be formed and patterned so as to receive the opening 220, which may extend to the conductive region 205. Next, a selective or anisotropic deposition process 228 may be performed in order to selectively deposit the activation layer 221 at the bottom 220B. For instance, the material of the activation layer 221 may be deposited on the basis of a sputter deposition process or any other respectively designed process in order to obtain an increased layer thickness at the bottom 220B compared to sidewall portions 220S of the opening 220. A corresponding material deposition outside the opening 220 may also occur, and such material may be removed, for instance, on the basis of a CMP process, as previously explained with reference to FIG. 1h. Prior to or after a corresponding CMP process for removing excess material of the layer 221 outside the opening 220, a corresponding isotropic etch process may be performed in order to remove material from the sidewall portions 220S, while maintaining a significant portion at the bottom 220B, due to the significantly increased thickness compared to the corresponding thickness at the sidewall portions 220S. In some cases, depending on the process strategy and the device requirements, an appropriate conductive material may be deposited as a base material for the activation layer 221, substantially without forming any additional materials on sidewall portions of the opening 220S, wherein the catalyst material may be incorporated in a separate treatment. In other illustrative embodiments, any appropriate barrier material may be formed, for instance by sputter deposition and the like, in order to cover the sidewalls 220S, wherein, in a final phase of the corresponding sputter process, a corresponding back-sputter process may be performed to substantially expose the activation layer 221.

FIG. 2b schematically illustrates the semiconductor device 200 during an electroless deposition process 224 in order to fill the opening 220 with an appropriate metal material 225, wherein the corresponding growth direction is substantially vertically oriented due to the selective provision of the activation layer 221 at the bottom 220B. It should be appreciated that the process sequence during the process 228 for selectively providing the activation layer 221 may result in a high degree of flexibility, since a pronounced selectivity during the actual deposition of the material of the layer 221 may not be required, since unwanted portions may be removed prior to the electroless deposition process 224. In other cases, depending on the type of material of the region 205, a selective growth may be obtained during the process 228 on the basis of the underlying material. For example, the respective process parameters of the process 228 may be adjusted so as to obtain adhesion of the material 221 on the region 205, while substantially preventing a deposition on the dielectric material of the layer 204. To this end, vapor deposition techniques, electroless deposition and the like may be used.

FIG. 2c schematically illustrates the semiconductor device 200 in accordance with other illustrative embodiments, in which the activation layer 221 may be formed by any appropriate deposition technique, thereby providing a high degree of flexibility in depositing the material 221, irrespective of the material composition of the region 205. For example, the region 205 may be comprised of silicon, silicon/germanium, metal silicide, when the region 205 represents respective contact areas at the device level. Similarly, the region 205 may comprise copper, copper alloys, conductive cap layers and the like when the metallization level may be considered. In these cases, a plurality of appropriate deposition techniques may be used, wherein a subsequent removal of excess material of the layer 221 may be accomplished on the basis of a selective etch process. As shown in FIG. 2c, a corresponding fill material 227 may be provided within the opening 220 and may also form a layer 227A, depending on the specifics of the corresponding deposition process for providing the fill material 227. For instance, well-established spin-on techniques may be used for forming the material 227, which may be comprised of polymer materials, resist materials and the like. Next, an etch process 229 may be performed on the basis of a selective etch chemistry, which may provide a significantly reduced etch rate for the material of the layer 204 compared to the materials 227 and 221. Consequently, these materials may be removed by the process 229, while the bottom of the opening 220 may reliably remain covered. It should be appreciated that typically highly selective etch chemistries may be available for a plurality of metal-containing materials with respect to dielectric materials, which may be efficiently used for the process 229.

FIG. 2d schematically illustrates the semiconductor device 200 in an advanced stage of the etch process 229. At this stage, a portion of the fill material 227R is still present and covers the material 221, while the sidewall portions 220S are increasingly exposed during the process 229. The etch process 229 may be reliably controlled on the basis of an appropriate endpoint detection signal, if a plasma-based dry etch process is used. That is, during an advanced stage of the etch process 229 as illustrated in FIG. 2d, significant portions of the material 227R may be released into the etch ambient, thereby providing a corresponding detection signal. If the material 227R may not form a corresponding well detectable species, a respective material component may be added to the material 227 in order to enhance the detectability. Upon exposure of the layer 221, the corresponding detection signal may significantly decrease, thereby indicating the depletion of the material 227. After exposing the material 221 at the bottom 220B, the process 224 may be performed as previously described.

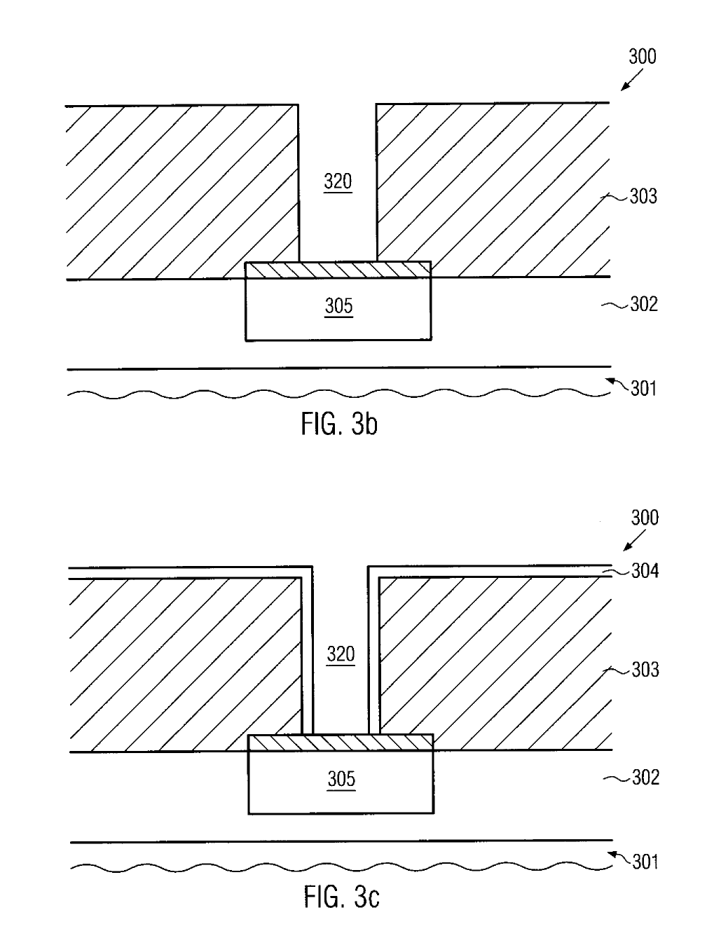

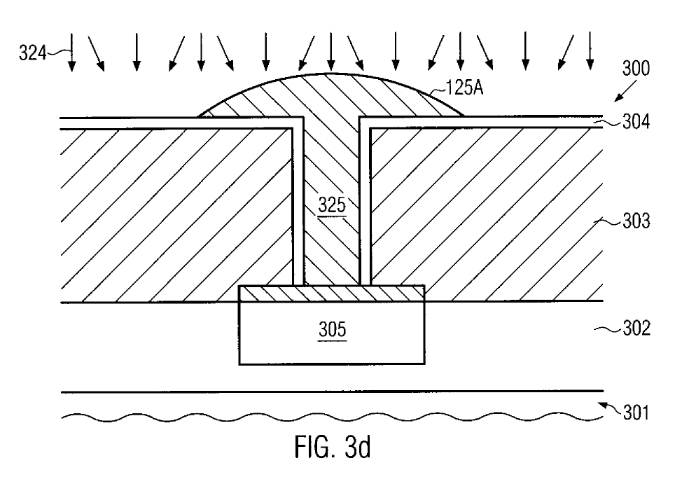

With reference to FIGS. 3a-3d, further illustrative embodiments will now be described, in which the corresponding activation layer or catalyst material may be provided within a restricted defined area, prior to the formation of a respective dielectric layer receiving a corresponding opening connecting to the restricted area.

FIG. 3a schematically illustrates a semiconductor device 300 comprising a substrate 301 having formed thereabove a material layer 302, such as a semiconductor layer, a dielectric layer and the like. In the material layer 302, a restricted device region 330 may be defined, for instance by providing a conductive region within a dielectric material, when the layer 302 represents a dielectric layer. In other cases, the restricted device region 330 may represent a metal line of a metallization layer, wherein the region 305 may be comprised of copper, copper alloys or any other appropriate material composition. An activation layer 321 is formed on the restricted device region 330 and may represent any appropriate material having formed therein or thereon an appropriate catalyst material, as previously explained. In some illustrative embodiments, the region 305 may represent a metal line, while the activation layer 321 may provide respective diffusion blocking characteristics in order to represent a cap layer for the region 305. In other cases, an additional cap layer, for instance comprised of a compound of cobalt, tungsten, phosphorous or boron, and the like, may be provided, which are well-known cap materials for copper-based metal lines.

The semiconductor device 300 as shown in FIG. 3a may be formed on the basis of the following processes. After providing the substrate 301 which may have formed therein any circuit elements, as previously explained, the layer 302 may be formed, for instance by depositing any appropriate dielectric material, when a metallization layer is considered. Thereafter, the respective opening, such as a trench, may be formed and an appropriate conductive material, such as copper or alloys thereof or any other material composition, may be deposited, for instance on the basis of well-established inlaid techniques as previously described. Next, the activation layer 321 may be formed, for instance by selective electrochemical deposition, wherein the material of the region 305 may act as a catalyst material. In other cases, the activation layer 321 may be deposited by any other deposition technique and may subsequently be patterned so as to cover the restricted device region 330. In other cases, a cap layer may be formed on the metal region 305, for instance by self-aligned techniques or by any other appropriate deposition technique, and subsequently an appropriate catalyst material may be incorporated into the respective cap layer by any appropriate treatment, such as plasma treatment, ion implantation and the like, in order to provide the activation material 321, at least at a surface portion of the corresponding cap layer.

FIG. 3b schematically illustrates the semiconductor device 300 in a further advanced manufacturing stage, in which a corresponding dielectric layer 303 may be provided which may have formed therein a corresponding opening 320, such as a via opening or a contact opening, as previously described. The opening 320 may extend to the activation layer 321, thereby exposing a portion thereof. The dielectric layer 303 and the opening 320 may be formed on the basis of well-established anisotropic patterning sequences, wherein, in some illustrative embodiments, the activation layer 321 may also act as an efficient etch stop layer, which may allow, in some illustrative embodiments, to omit a respective etch stop material in the dielectric layer 303 which may be advantageous in terms of reduced overall permittivity of the dielectric material, if highly advanced metallization structures are considered.

FIG. 3c schematically illustrates the semiconductor device 300 with one or more barrier layers 304 formed within the opening 320 in order to provide the required diffusion blocking characteristics, adhesion and the like at the interface between the dielectric material and the metal-containing material still to be filled in. It should be appreciated that the barrier layer 304 may be comprised of several materials and sub-layers depending on the device requirements. Furthermore, the barrier layer 304 may be formed so as to reliably cover the sidewall portions 320S, while substantially exposing the activation layer 321. This may be accomplished on the basis of advanced deposition techniques, including re-sputter techniques, highly selective deposition recipes and the like or any other techniques previously described.

FIG. 3d schematically illustrates the semiconductor device 330 during an electroless deposition process 324 performed on the basis of the activation layer 321 in order to fill the opening 320 with conductive material 325, such as copper, copper alloys and the like. Thereafter, any excess material created during the process 324 may be removed on the basis of CMP and the like.

As a result, disclosed herein is an enhanced technique for reliably filling high aspect ratio openings on the basis of an electroless deposition technique, wherein an appropriate activation material or nucleation material may be provided at the bottom of the opening in order to obtain a substantially vertical growth direction without undue lateral deposition of the material during the electroless deposition process. Consequently, the bottom-to-top fill behavior may be obtained without highly complex deposition strategies and etch chemistries, as are typically required in electroplating techniques. Consequently, a plurality of metal-containing materials may be efficiently deposited in respective openings, such as contact openings, via openings, trenches and the like, thereby providing the potential for further device scaling with increased crystallinity of the respective materials, while at the same time providing a high deposition rate.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing an exposed surface of an activation layer selectively at a bottom of an opening formed in a material layer of a semiconductor device, said activation layer comprising a species for initiating an electrochemical deposition process when being in contact with a specified electrolyte solution; and
applying said specified electrolyte solution in said opening to perform an electrochemical process for filling said opening with a conductive material from bottom to top on the basis of said exposed surface of the activation layer.

2. The method of claim 1, wherein providing said exposed surface of the activation layer comprises forming said opening and forming said activation layer in said opening.

3. The method of claim 2, wherein said activation layer is formed by a method that comprises forming said activation layer on exposed surfaces of said opening and covering sidewalls of said activation layer by a spacer material exhibiting a substantially inert behavior during the electrochemical process.

4. The method of claim 2, further comprising removing excess material of said activation layer outside said opening.

5. The method of claim 2, wherein said activation layer is formed by a selective deposition technique having a reduced deposition rate at sidewall surfaces of said opening compared to the bottom of said opening.

6. The method of claim 5, further comprising performing an etch process for removing material of said activation layer at the sidewalls of said opening.

7. The method of claim 1, wherein providing said exposed surface of the activation layer comprises forming said activation layer locally on a restricted device region of said semiconductor device, forming said material layer and forming said opening above said restricted device region to expose a portion of said activation layer.

8. The method of claim 7, wherein said restricted device region comprises a metal line of a metallization layer.

9. The method of claim 1, wherein said activation layer comprises at least one of platinum, palladium, silver, copper and cobalt.

10. The method of claim 1, wherein said specified electrolyte solution comprises at least one of copper, cobalt, nickel, silver, gold and alloys of any of these metals.

11. A method comprising:
forming an opening in a material layer of a semiconductor device;
providing an exposed catalyst material selectively at a bottom of said opening, said catalyst material initiating an electrochemical reaction upon contact with a specified electrolyte solution; and
filling said opening from bottom to top with a metal-containing material by applying said specified electrolyte solution.

12. The method of claim 11, wherein said catalyst material is provided in said opening by a directional ion bombardment.

13. The method of claim 12, wherein said directional ion bombardment comprises at least one of an ion implantation process and an ionized physical vapor deposition process.

14. The method of claim 11, wherein providing said catalyst material comprises forming an activation layer comprising said catalyst material on exposed surfaces of said opening.

15. The method of claim 14, further comprising covering sidewalls of said opening by a spacer layer after forming said activation layer.

16. The method of claim 14, further comprising removing said activation layer from sidewalls of said opening while covering the bottom of said opening to reduce material removal of said activation layer at the bottom.

17. The method of claim 11, wherein said metal-containing material comprises at least one of copper, cobalt, nickel, silver, gold and alloys of any of these metals.

18. A method, comprising:
forming an activation layer on a restricted area of a semiconductor device;
forming a dielectric layer above said restricted area;
forming an opening in said dielectric layer to expose a portion of said activation layer; and
filling said opening by an electrochemical deposition process using said exposed portion of the activation layer for initiating said electrochemical deposition process.

19. The method of claim 18, wherein said restricted area represents one of a metal region of a metallization layer and a contact area of a transistor element.

20. The method of claim 18, further comprising forming a conductive barrier layer on sidewalls of said opening prior to filling said opening by said electrochemical deposition process.
